(19) United States
(12) Patent Application Publication
(10) Pub. No.: US 2005/0117415 A1
(43) Pub. Date: Jun. 2, 2005

(54) Method and apparatus for replaying a recording medium

(76) Inventor: Jorg Pietruszka, Bochum (DE)

Correspondence Address: WARE FRESSOLA VAN DER SLUYS &;ADOLPHSON, LLP, BRADFORD GREEN BUILDING 5, 755 MAIN STREET, P O BOX 224, MONROE, CT, 06468, US

(21) Appl. No.: 10/507,881

(22) PCT Filed: Mar. 15, 2002
(86) PCT No.: PCT/IB02/00789

(51) Int. Cl. G11C 7/00

(52) U.S. Cl. 365/200

(57) ABSTRACT

The present invention relates to a method and an apparatus for replaying a recording medium that can be used for multiple recording of data. The method comprises the steps of retrieving replay start position data associated with a recording medium to be replayed; starting replaying of said recording medium at a replay start position according to said replay start position data retrieved if such data exist and a resume function is activated; otherwise; starting replaying of said recording medium either at a default starting positions or at a starting position selected by a user; and storing actual reading position data as replay start position data associated with the recording medium when replay operation is stopped for ejecting said recording medium or for switching off.

### CROSS-REFERENCE TO RELATED APPLICATION

This application is the U.S. National Stage of International Application Number PCT/IB02/00789 filed 15 Mar. 2002 in the English language and published 25 Sep. 2003 in that language under International Publication Number WO 03/079360 A1 with International Search Report.

### BACKGROUND OF THE INVENTION

1. Technical Field

The present invention relates to a method and an apparatus for replaying a recording medium that can be used for multiple recording of data.

2. Discussion of Related Art

Today's apparatuses for replaying compact discs (herein after also referred to as “CD”), in particular such apparatuses or CD players used in automotive vehicles store the position on the CD when the apparatus or player is switched off and restart replaying audio information from the CD at this position when the apparatus or player is started again. This function is known as “auto-resume function”.

This auto-resume function is also requested for MP3 players which are capable of replaying recording media like memory cards or multimedia cards (MMC) which are used for storing audio information according to the MP3 standard.

U.S. Pat. No. 5,740,304 describes a method and an apparatus for replaying a recording medium from any bookmark-set position thereon. The known replay apparatus comprises a replay section, an input section, a storage section and a control section. The control section allows replay start position data to be produced when the input section is operated while the replay section is replaying a specific piece of audio and/or video data. This replay start position data is stored in the storage section together with discrimination data of the recording medium. Instead of using discrimination data of the recording medium it is also possible to generate collation data for specifying a recording medium on the basis of at least management data of the recording medium.

Thus, it is possible to start the replay of the recording medium from a portion designated by the replay start position stored in a memory of the storage section when the recording medium is accommodated in the replaying apparatus again after ejection.

Further, U.S. Pat. No. 5,463,601 discloses a CD-ROM replaying or reproducing apparatus that includes a memory for sequentially storing therein progression data of a program that plays. If the playback control of the CD-ROM is purposely stopped by a bookmarker switch or when the playback control of the CD-ROM is interrupted unintentionally the progression data of the program are saved by the memory together with volume ID (identification) and time data from the table of contents (TOC) information. However, it is also possible to stop play-back control without storing information about the CD-ROM disc and without setting a bookmarker flag.

In case that this known apparatus is switched on again and the bookmarker flag is set, volume ID data and time data are read out from the TOC information of the CD-ROM. This information is compared with the stored information and in case that the CD-ROM inserted into the apparatus is identified as that re-played during the last operation period it will be replayed starting from a position corresponding to the stored progression data of the program.

### SUMMARY OF THE INVENTION

The object of the invention is to provide a method and an apparatus for replaying a recording medium that allow replaying or reproducing of a program to be resumed from a recording medium that can be used for multiple recording of data starting at the same location on the recording medium even if the recording medium has been reinserted into the apparatus after being ejected therefrom.

According to the present invention this object is achieved by a method that comprises the steps of: retrieving replay start position data associated with a recording medium to be replayed; starting replaying of the recording medium at a replay start position according to the replay start position data retrieved if such data exist and if a resume function is activated; otherwise starting replaying of the recording medium either at a default starting position or at a starting position selected by a user; and storing actual reading position data as replay start position data associated with the recording medium when replaying operation is stopped for ejecting the recording medium or for switching off an apparatus used for replaying the recording medium.

According to a first embodiment of the present invention replay start position data are stored on the recording medium itself. Thus, it is possible to continue with replaying or reproducing a program on a recording medium at the location where the former period of replaying operation ended, even if the recording medium is inserted into a different replay apparatus that supports the inventive auto-resume function.

According to another embodiment of the present invention replay start position data are stored in memory means of an apparatus for replaying said recording medium together with recording medium identification data, wherein these recording medium identification data are generated from information recorded on the recording medium.

Since the program recorded on the recording medium might be changed between a former and a later replaying period such change of the program can be identified so that the auto-resume function is canceled since it doesn't make sense to continue with replaying a program that has been changed in general and might have been changed particularly at that position where replaying of the former program was stopped.

For generating recording medium identification data information obtained from the recording medium can be used. In particular, contents identification information, information about the occupied memory space, information about the number of recorded items, and/or information about the duration of the recorded items can be used to generate recording medium identification data. Further, it is possible to calculate a checksum from recorded information and use it as recording medium identification data.

Furthermore, according to an advantageous refinement of the present invention recording medium identification data and associated replay start position data are stored in a list. So it is possible to apply the auto-resume function not only to a single recording medium but to plurality of individual recording media even if another recording medium was inserted into the replay apparatus in the mean time.

The inventive method can be advantageously performed with an apparatus for replaying a recording medium, that comprises replaying means for reading and replaying information recorded on a recording medium; control means for controlling reading and replaying of information recorded on the recording medium, this control means further comprises generating means for generating recording medium identification data; and memory means for storing actual reading position data as replay start position data together with recording medium identification data when the apparatus is switched off and/or the recording medium has to be ejected.

To improve the handling and the operation of the inventive apparatus, it further comprises output means for visually or acoustically prompting a user for selecting a replay starting mode, and input means for inputting a replay starting mode selecting command. Thus, it is possible for a user after inserting a recording medium into the inventive apparatus to decide whether or not he/she wants to use the auto-resume function.

According to a preferred embodiment of the present invention the memory means are adapted to store a list of recording medium identification data each associated with replay start position data.

Furthermore, it is possible that the apparatus is provided with recording means for recording replay start position data on the recording medium itself.

### BRIEF DESCRIPTION OF THE DRAWINGS

The invention will be explained in more detail with reference to the accompanying drawings. In the drawings:

FIG. 1 is a simplified schematic block diagram showing an apparatus for replaying a recording medium; and

FIG. 2 is a simplified schematic flow chart showing the processing of a replay apparatus when performing the inventive method.

### DETAILED DESCRIPTION OF PREFERRED EMBODIMENTS

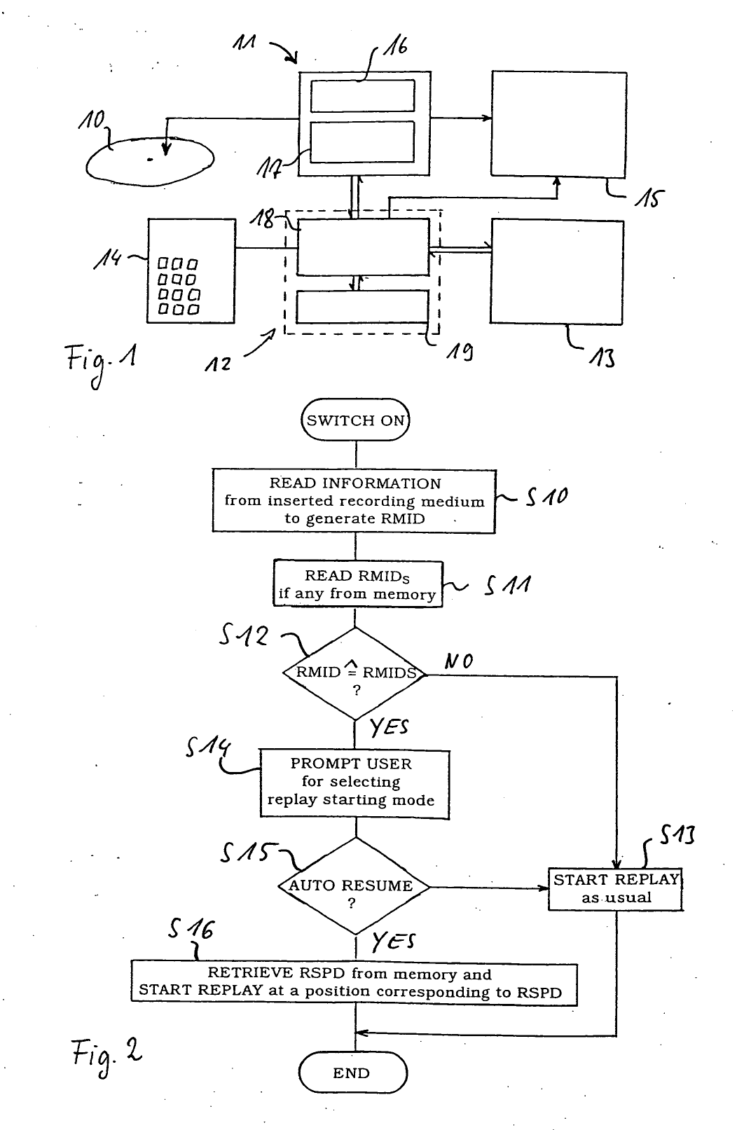

According to FIG. 1 an apparatus for replaying a recording medium 10 comprises replaying means 11, control means 12 and memory means 13. Further, the apparatus includes preferably input means 14 and output means 15 which provide a user interface for controlling replaying or reproducing operation of the apparatus. The output means 15 may be formed by a separate display. However, as indicated in FIG. 1 the output means 15 of the user interface may be integrated into or form a part of output means 15 used for replaying.

The recording medium 10 is illustrated as a disc but can be any usual recording medium that allows arbitrary reading and writing access to the memory regions provided thereon. For example memory cards or multimedia cards as well as rewritable CD or DVD can be used.

The replaying means 11 includes reading means 16 for pick-up or reading data from the recording medium and for supplying audio and/or video information to the output means 15 for replaying audio and/or video information, i. e. for reproducing or playing a piece of music or a video clip or video film. In the following, pieces of music, pictures and films stored on the recording medium 10 are also called programs.

Further, the replaying means includes recording means 17 for recording data onto a recording medium.

For controlling the operation of the replay apparatus the control means 12 comprises a controller section 18 that is connected to the input means for receiving control information input by a user. Further, the controller section 18 is connected with the replaying means 11 to supply control signals for controlling reading and replaying a program and for receiving information retrieved from the recording medium. To prompt the user for additional information the controller section is further connected with the output means 15.

In addition, the control means 12 comprises generating means 19 for generating recording medium identification data RMID. Therefore, the generating means 19 is connected with the controller section to receive the necessary data retrieved from the recording medium 10 and to supply recording medium identification data RMID to the controller section so that these data can be stored together with reading position data RPD in the memory means 13.

The operation of the inventive apparatus for performing the method according to the present invention will be described with reference to FIG. 2.

After a recording medium is inserted or accommodated in a corresponding receiving device (not shown) of the replay apparatus and the power is switched on information is read from the inserted recording medium in step S10 and supplied to the generating means 19 so as to generate recording medium identification data RMID. Thereafter stored recording medium identification data RMIDS is read from the memory in case that any such data are stored therein (Step S 11).

Then, recording medium identification data RMID related with the recording medium inserted into the apparatus is compared with that read from the memory 13 in step S12. If it is determined in step 12 that no auto-resume information is stored the memory, i. e. the recording medium identification data RMID of the inserted recording medium 10 does not correspond with any of the stored recording medium identification data RMIDS, the method proceeds to step S 13 for starting replay in the usual way.

However, if it is determined in step S12 that auto-resume information is stored in the memory 13 the user is preferably prompted in step S14 for selecting a replay starting mode, i. e. for selecting either the usual replay starting mode or the auto-resume replay starting mode. If the user selects in step S 14 the auto-resume replay starting mode the method proceeds with step 16, i. e. replay start position are retrieved from the memory 13 and used as reading position data RPD during starting replay. Thus, replaying of the recording medium will be started at a position corresponding to the retrieved replay start position data.

In case that not only auto-resume data of a single recording medium is stored in memory 13 but a list of a plurality of recording media, all stored recording medium identification data RMIDS are compared with that generated for the actually inserted recording medium until auto-resume information, i. e. a data set consisting of recording medium information data RM BD and replay start position data RSPD which are related to the actually inserted recording medium is found.

Instead of automatically checking whether there are auto-resume data stored in the memory is also possible to enter the described method only if it is requested by the user by inputting a corresponding auto-resume function signal.

When the replaying operation is interrupted for switching off the apparatus or for ejecting the inserted recording medium 10 so that it can be replaced by another recording medium the actual reading position data RPD at the time of stopping the replaying operation is stored either automatically or only upon a user command input, together with the recording medium identification data in the memory 13. Thus, it is possible to start the next period of replaying the program from the recording medium 10 at the same position at which the former period of replaying was terminated.

Instead of storing the replay start position data in the memory 13 of the replay apparatus it is also possible to record this information on a specific portion of the recording medium itself. In this case it is possible to use the auto-resume replay starting mode in any apparatus that supports the inventive method. In this case upon inserting a recording medium and switching on the power supply of the apparatus it is checked after reading information from the inserted recording medium whether there is a replay start position data stored on the disc i. e. recording medium. In this case the user is prompted for selecting a replay starting mode in case that there is replay start position data stored. Otherwise replaying is started as usual without prompting the user.

Here, it is also possible that the existence or none-existence of replay start position data RSPD stored on the recording medium 10 is only checked for performing auto-resume replay starting mode upon user request in-put via input means 14.

For generating recording medium identification data a recording medium identifier will not be used since such an identifier does not ensure that the information stored on the recording medium was not changed after storing auto-resume information. Therefore, recording medium identification data are preferably generated from program information recorded on the recording medium 10. For example, contents identification information can be used. Further, the occupied memory space of the recording medium can be determined for generating individual recording medium identification data. Another possibility of generating recording medium identification data is to simply count the recorded items and to use the number thereof as identification data. Similarly, the total duration of the recorded items can be used as recording medium identification data. Furthermore, recording medium identification data can be also calculated from both the number of items and the total or individual duration. Further, a checksum can be calculated from the recording information and used as the recording medium identification data.

The inventive method can be used with any replaying apparatus the hardware of which supports the different method steps.

In particular, it is possible to use the inventive method together with a mobile telephone in case that it is adapted to receive e. g. an MP3 memory card or a multimedia card for downloading MP3 music information from the internet and in case that a replaying apparatus is integrated in the mobile phone. In this case the inventive method can be implemented for example over a speed dial function. In this case a “store”-key that might be realized as a soft key may be pressed followed by entering “1” via the usual key pad to store the current track position, i. e. the actual reading position data.

If the recording medium is inserted again after it was replaced by another medium it is possible to commence replaying from the stored position simply by pressing a “resume”-key followed by pressing “1” on the key pad. To avoid erroneous operation of the replay apparatus integrated in a mobile phone the resume function should be only available if the inserted recording medium has be clearly identified as that to which the stored position data relate.

1. A method for replaying a recording medium that can be used for multiple recording of data; comprising the steps of:
retrieving replay start position data associated with a recording medium to be replayed,
starting replaying of said recording medium at a replay start position according to said replay start position data retrieved if such data exist and a resume function is activated, otherwise
starting replaying of said recording medium either at a default starting position or at a starting position selected by a user, and
storing actual reading position data as replay start position data associated with the recording medium when replay operation is stopped for ejecting said recording medium or for switching off.

2. The method according to claim 1, wherein replay start position data are stored on the recording medium itself.

3. The method according to claim 1, wherein replay start position data are stored in memory means of an apparatus for replaying said recording medium together recording medium identification data.

4. The method according to claim 3, wherein recording medium identification data are generated from information recorded on said recording medium.

5. The method according to claim 4, wherein contents identification information is used for generating recording medium identification data.

6. The method according to claim 4, wherein the occupied memory space is used to generate recording medium identification data.

7. The method according to claim 4, wherein the number of recorded items is used to generate recording medium identification data.

8. The method according to claim 4, wherein the duration of the recorded item is used to generate recording medium identification data.

9. The method according to claim 4, wherein a checksum is calculated from recorded information as recording medium identification data.

10. The method according to claim 3, wherein recording medium identification data and associated replay start position data are stored in a list.

11. An apparatus for replaying a recording medium (10) that can be used for multiple recording of data, said apparatus comprising:
replaying means (11) for reading and replaying information recorded on a recording medium (10),
control means (12) for controlling reading and replaying of information recorded on said recording medium, said control means (12) further comprises
generating means (19) for generating recording medium identification data; and
memory means (13) for storing actual reading position data as replay start position data together with recording medium identification data when said apparatus is switched off and/or said recording medium (10) has to be ejected.

12. The apparatus according to claim 11 further comprising:
output means (15) for visually and/or acoustically prompting a user for selecting a replay starting mode, and
input means (14) for inputting a replay starting mode selecting command.

13. The apparatus according to claim 11, wherein said memory means (13) are adapted to store a list off recording medium identification data each associated with replay start position data.

14. The apparatus according to claim 11, further comprising recording means (17) for recording replay start position data on said recording medium.
